(19) United States
(12) Patent Application Publication
(10) Pub. No.: US 2022/0304142 A1
(43) Pub. Date: Sep. 22, 2022

(54) CIRCUIT BOARD TO REDUCE FAR END CROSS TALK

(71) Applicant: Intel Corporation, Santa Clara, CA (US)

(72) Inventors: Xiang LI, Portland, OR (US); Landon HANKS, Milwaukie, OR (US); George VERGIS, Portland, OR (US); James A. McCALL, Portland, OR (US)

(21) Appl. No.: 17/831,774

(22) Filed: Jun. 3, 2022

(51) Int. Cl. H05K 1/02; H05K 3/46

(52) U.S. Cl. CPC H05K 1/0218; H05K 3/4644; H05K 2201/10159

(57) ABSTRACT

Examples described herein relate to a system that includes: a circuit board comprising a plurality of layers and at least one conductive connection. In some examples, the at least one conductive connection is connected to a layer of the plurality of layers. In some examples, at least one layer of the plurality of layers comprises a conductive material. In some examples, the at least two layers of the plurality of layers comprise conductive material that extend in an axis towards the at least one conductive connection but do not overlap with the at least one layer of the plurality of layers comprising the conductive material.

### BACKGROUND

Volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein can be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory, JESD325, originally published by JEDEC in October 2013, DDR5 (DDR version 5, currently in discussion by JEDEC), LPDDR5 (currently in discussion by JEDEC), HBM2 (HBM version 2), currently in discussion by JEDEC, or others or combinations of memory technologies, and technologies based on derivatives or extensions of such specifications.

DDR5 unregistered (U), registered (R), load reduce (LR) dual in-line memory module (DIMM) connectors are defined as a surface mount connector (SMT) connector with 1:1 signal to ground ratio. DDR5 UDIMM, RDIMM, LRDIMM, and SODIMM are based on single ended signaling. DIMM connector performance is critical for channel performance.

FIG. 1 shows a perspective of a DDR5 pinout with an arrangement of signal pins and ground pins with a 1:1 signal-to-ground pin (S/G) ratio. The SMT connector signal pins are shielded by the ground pins as one ground pin placed between two data (DQ) signal pins to reduce the crosstalk between signal pins. DDR5 UDIMM, RDIMM, LRDIMM, and SODIMM utilize a signal and ground pin arrangement with 1:1 S/G ratio for DQ signals. DDR5 RDIMM and LRDIMM utilize a signal and ground pin arrangement with 1:1 S/G ratio for command/address (CA) signals.

FIG. 2 shows another view of a connector pin design. Signal pins connect DIMM gold fingers (GF) to corresponding motherboard (MB) SMT pads. Ground pins are positioned between signal pins and connect other DIMM gold fingers to corresponding motherboard (MB) SMT pads.

### BRIEF DESCRIPTION OF THE DRAWINGS

FIG. 1 shows an example of a DDR5 pinout with an arrangement of signal pins and ground pins with a 1:1 signal to ground pin (S/G) ratio.

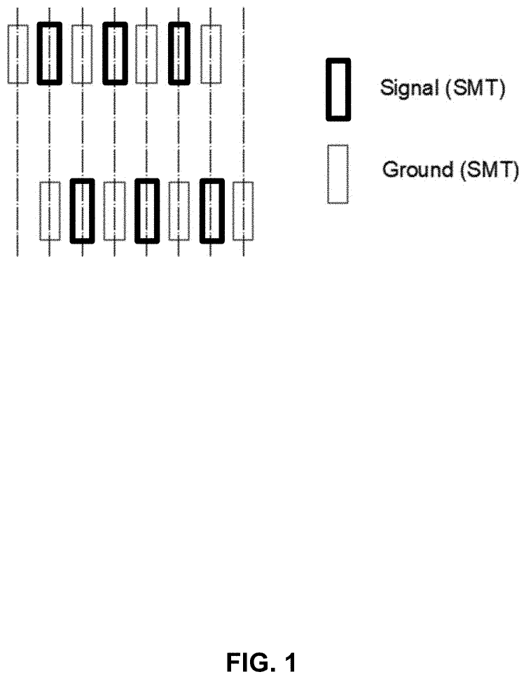

FIG. 2 shows another view of a connector pin design.

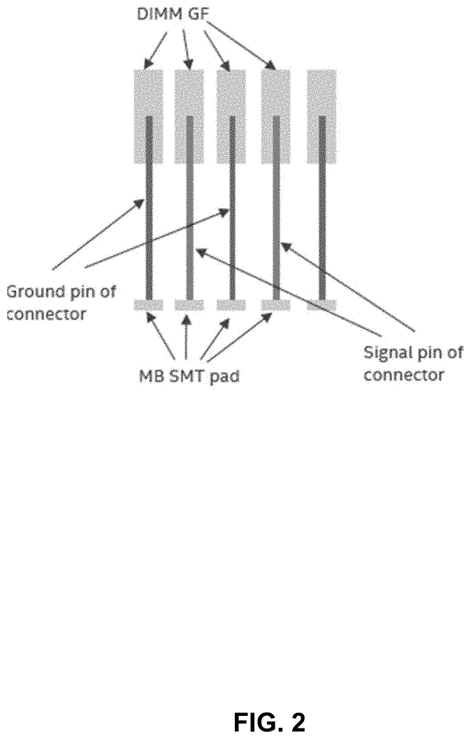

FIG. 3A depicts a side view of an example of an existing system with DIMM inserted to contact with pins.

FIG. 3B depicts a side view of an example system with DIMM inserted to contact with pins.

FIG. 3C depicts an example of pin to gold finger connection.

FIG. 3D depicts an example of a top down view of an arrangement of pins with a circuit board coupled to the pins.

FIG. 4 depicts an example of recessed conductive planes in one or more layers.

FIG. 5 depicts an example of electric field intensity graphs for non-recessed and recessed conductor in an L4 layer.

FIG. 6 depicts an example of a side view of an example system with DIMM inserted to contact with pins.

FIG. 7 depicts an example of structural support.

FIG. 8 depicts an example of impedance and cross talk for the DIMM of FIG. 3B with no structural support.

FIG. 9 depicts an example of impedance and cross talk with structural support and with recessing and no recessing for different layers.

FIG. 10 depicts an example process.

FIG. 11 depicts a system.

### DETAILED DESCRIPTION

Signals transmitted using different signal pins can experience cross talk whereby signals transmitted on one signal pin can cause interference to signals transmitted on one or more other signal pins. In some cases, crosstalk can be caused by capacitive, inductive, or conductive coupling. As is described herein, DDR5 connector crosstalk performance is related to internal conductor layers or planes in a motherboard. For example, conductor planes in a DIMM can be associated with an increase in electric field intensity and the electric field can cause an increase in cross talk among signals transmitted via signal pins.

At least to attempt to reduce cross talk among signals transmitted using signal pins in at least a DDR5 pin layout, some examples provide for recessed conductor layers in a DIMM or other circuit board. In some examples, the recessed region includes a dielectric material. In some examples, metal or other electrically conductive or non-electrically conductive rigid materials can be interspersed within the dielectric material of the recessed region to provide rigidity for the DIMM or other circuit board.

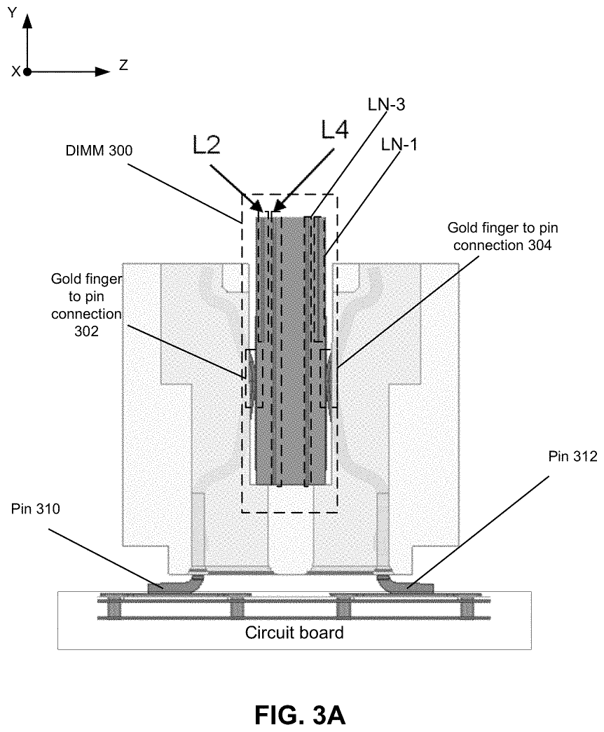

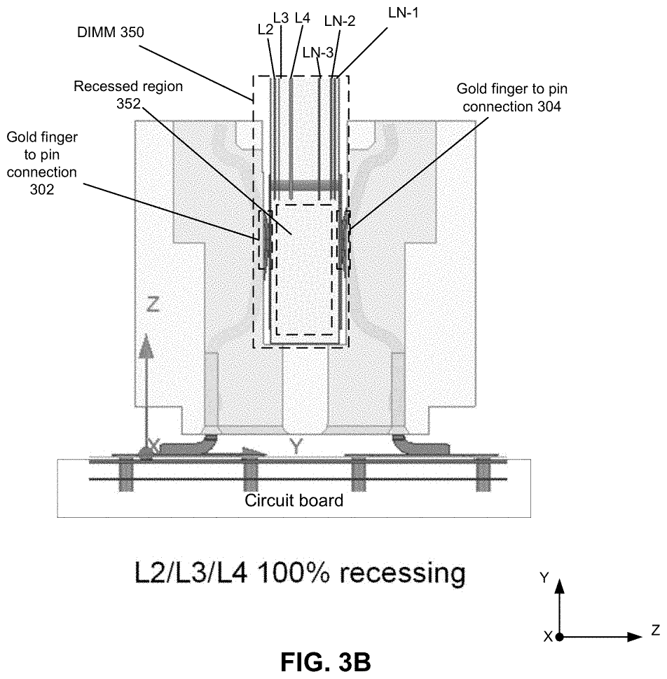

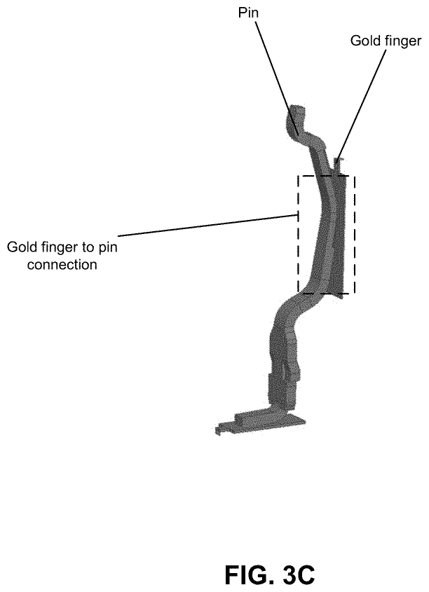

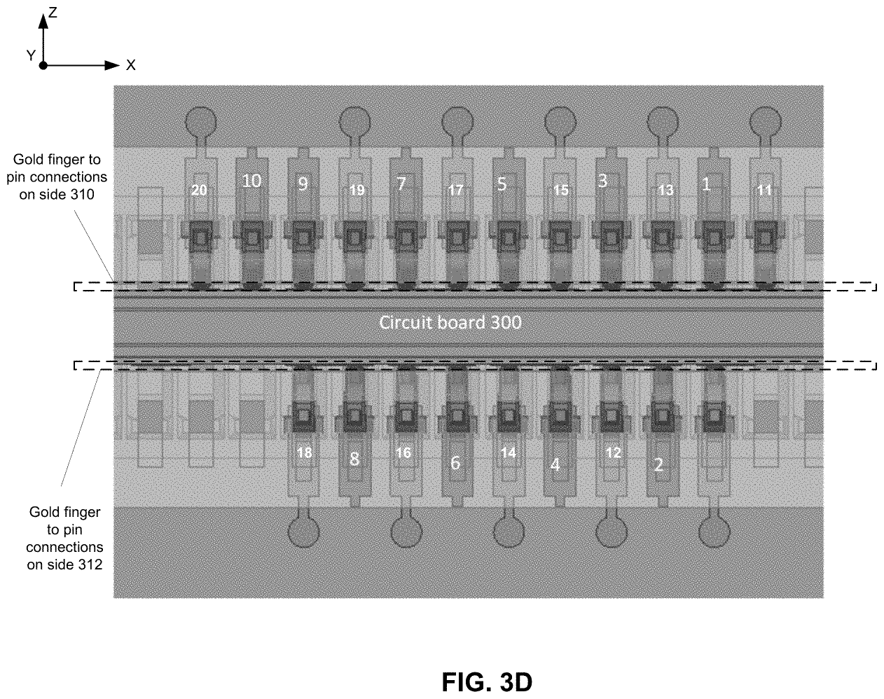

FIG. 3A depicts a side view of an example of an existing system with DIMM inserted to contact with pins. DIMM 300 can include gold fingers in contact with to pins. For example, connection 302 can include a gold finger on DIMM 300 that connects with pin 310. For example, connection 304 can include a gold finger on DIMM 300 that connects with pin 312. DIMM 300 can include multiple conductive layers L2, L4, . . . LN−3, and LN−1, where N can be a number of layers in a circuit board. In some examples, L2 includes a conductive layer (e.g., ground (GND)) that is recessed and does not extend in the (−)Y direction to overlap with connection 302. Similarly, layer LN−1 includes a conductive layer (e.g., GND) that is recessed and does not extend in the (−) Y direction to overlap with connection 304. In some examples, layer L4 includes a conductive layer (e.g., signal) that is not recessed and extends in the (−)Y direction to overlap with connection 302. Similarly, layer LN−3 includes a conductive layer (e.g., signal) that is not recessed and extends in the (−)Y direction to overlap with connection 304.

The recessed layer L2 can be used to control connector impedance at the gold finger-to-connector 302 in order to reduce electric field reflection. Similarly, the recessed layer LN−1 can be used to control connector impedance at the gold finger-to-connector 304 in order to reduce electric field reflection. The layer L4, further from golden finger connection 302 than L2, is not recessed, and may contribute electric field reflection that contributes to far end cross talk. Similarly, the layer LN−3, further from golden finger connection 304 than LN−1, is not recessed, and may contribute electric field reflection that contributes to far end cross talk.

FIG. 3B depicts a side view of an example system with DIMM inserted to contact with pins. As shown, in DIMM, conductor layers L2, L3, L4, LN−3, LN−2, and LN−1 layers are recessed so that conductor layers do not overlap with gold finger contacts 302 or 304 in the (−)Y direction. A recessed region 352 can be formed by an absense of conductor layers. Recessed region 352 can include a dielectric material. Layers between conductive layers can include dielectric material such as FR4 dielectric. Conductive layers and dielectric layers can be glued together, connected, or affixed using other techniques. A conductor layer can include a conductive metal such as one or more of: copper, bronze, or an alloy.

FIG. 3C depicts an example of pin to gold finger connection.

FIG. 3D depicts an example of a top down view of an arrangement of pins with a circuit board coupled to the pins. Circuit board 300 can include gold finger connections that are coupled to Pins 1, 2, 3, . . . , 9, 10 on sides 310 and 312. For example, pins 1-10 can be utilized as signal pins and pins 11-20 can be utilized as ground pins. For example, pins 1-10 can be assigned to a memory controller (MC) (not shown). For example, pins 11-20 can be assigned to a memory device (e.g., dynamic random access memory (DRAM)). Pins 1-20 can convey CA or DQ signals.

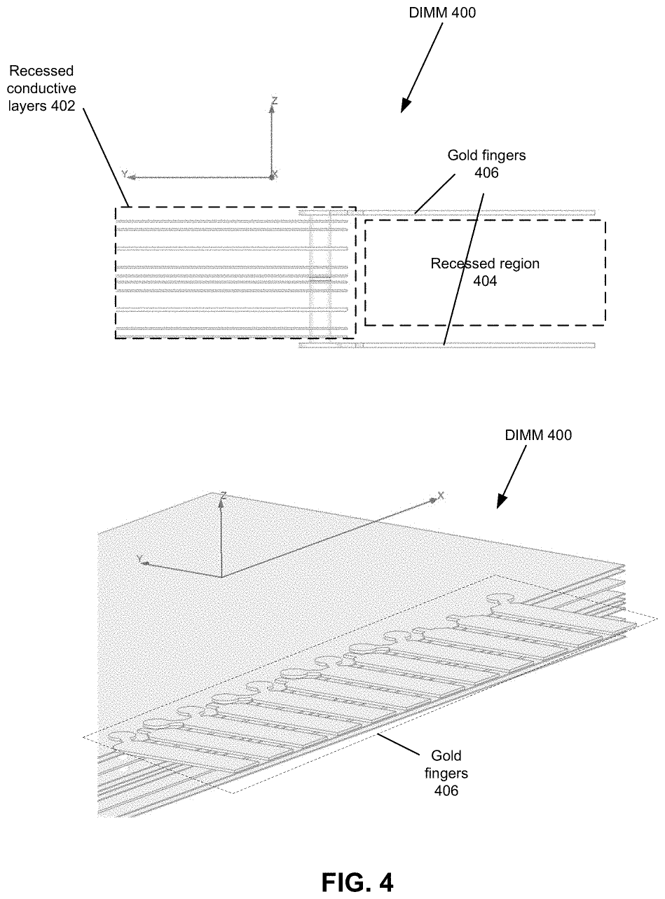

FIG. 4 depicts an example of recessed conductive planes in one or more layers. Recessed conductive layers 402 are formed to provide a recessed region 404 of DIMM 400. Recessed conductive layers 402 do not overlap with gold fingers 406 in the (−)Y direction. Recessed region 404 does not include portions of recessed conductive layers 402. DIMM is connected to gold fingers 406.

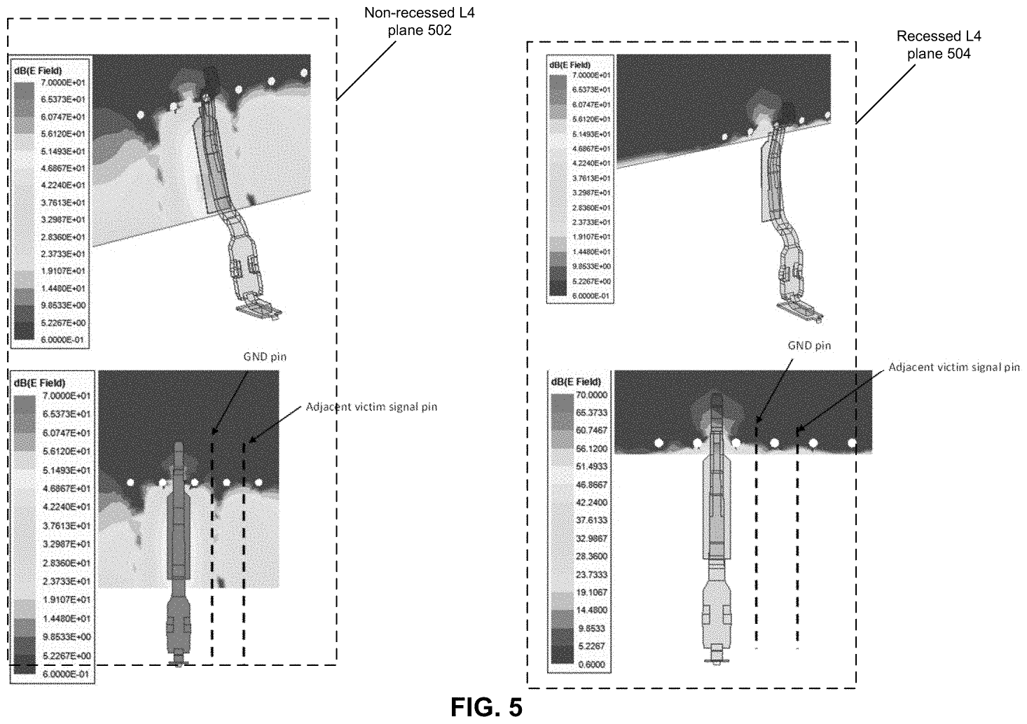

FIG. 5 depicts an example of electric field intensity graphs for non-recessed and recessed conductor in an L4 layer. As shown in graph 502, an electric field caused by non-recessed conductive plane affects adjacent signal pin and causes more crosstalk to adjacent victim pins than if the L4 layer includes a recessed conductor, as shown in graph 504.

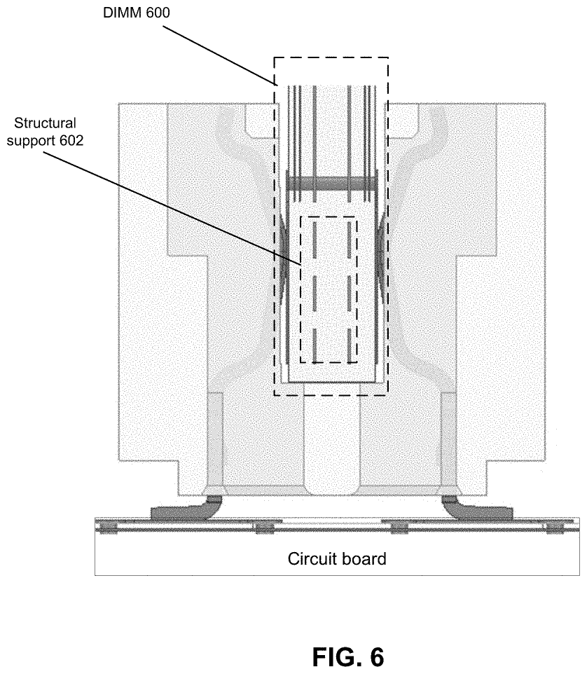

FIG. 6 depicts an example of a side view of an example system with DIMM inserted to contact with pins. In this example, DIMM 600 includes recessed conductor layers in a similar manner as that of DIMM 350. DIMM 600 also includes structural support 602 in recessed region 350. For example, structural support 602 can be formed of material such as one or more of: metal (e.g., copper, bronze, or an alloy). Structural support 602 can provide support for DIMM 600 to resist twisting or bending of DIMM 600 in the Y direction.

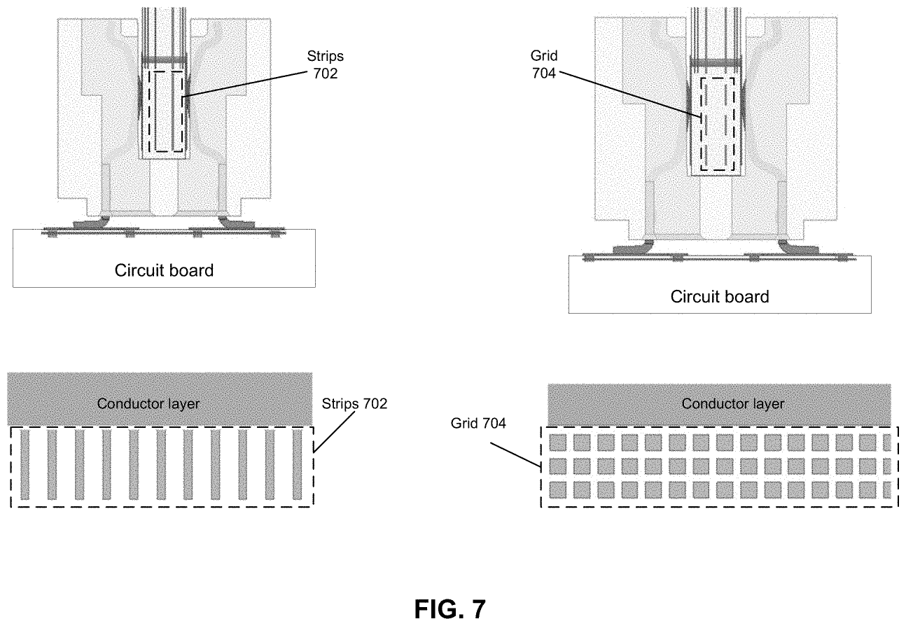

FIG. 7 depicts an example of structural support. As shown, structural support can be different shapes. Examples are not limited to the shapes shown. For example, structural support strips 702 can provide one or more rectangular strips of materials that are separated from one another and from conductor layer (e.g., L2, L3, L4, LN−3, LN−2, and/or LN−1 of FIG. 3B) or are separated by a dielectric material. For example, structural support grid 704 can provide one or more square shaped materials separated by dielectric material from one another and conductor layer (e.g., L2, L3, L4, LN−3, LN−2, and/or LN−1 of FIG. 3B). For example, materials of structural support can include conductive metals such as copper, bronze, or an alloy mixture of metals). Examples of other shapes of structural support can include circular, oval, or a mixture of circular, oval, squares, and rectangles.

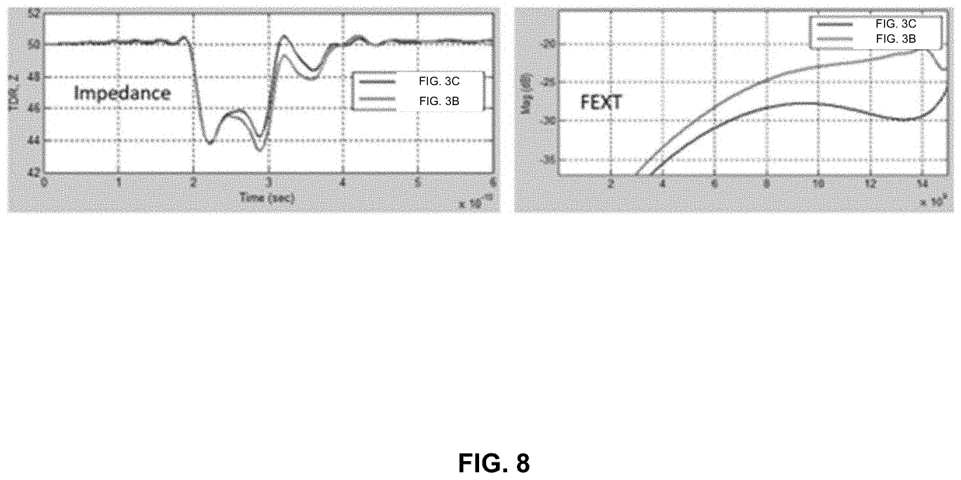

FIG. 8 depicts an example of impedance and cross talk for the DIMMs of FIGS. 3B and 3C with no structural support. As shown, impedance of DIMM with recessed region and no recessed region is similar, but reduced connector crosstalk, which can improve the DDR5 channel performance. Impedance can indicate a measurement of rise time of a signal from 0 to 100% amplitude.

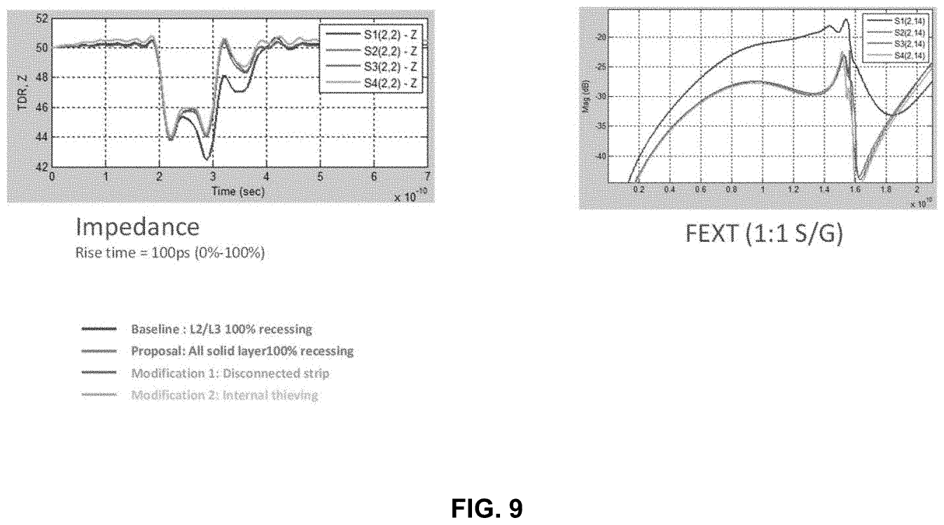

FIG. 9 depicts an example of impedance and cross talk with structural support and with recessing and no recessing for different layers. For example, impedance and cross talk are shown for L2-L3 fully recessed with strips or square shaped structural support. In addition, impedance and cross talk are shown for L2-L4 recessed with strips and square structural support. Impedance and cross talk can be similar with structural support and no structural support.

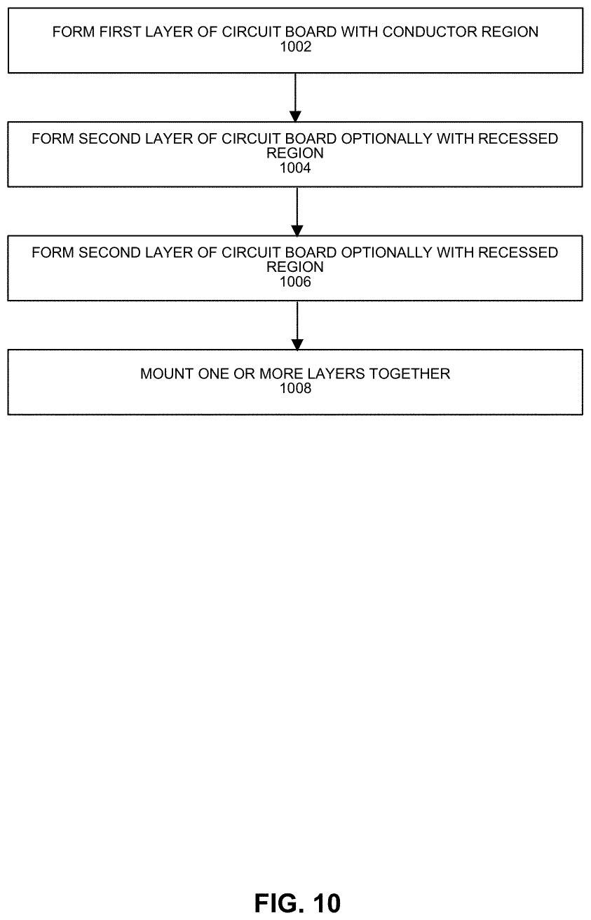

FIG. 10 depicts an example process to construct a circuit board. At 1002, a first layer of a circuit board can be formed. The first layer can include a conductor that includes one or more conductive connectors. For example, one or more conductive connectors can include one or more gold fingers capable of connection with signal or ground pins.

At 1004, a second layer of the circuit board can be formed. The second layer can include a conductor and/or dielectric. In cases where the second layer includes a conductor, the second layer can include a recessed region that does not overlap with the one or more conductive connectors. In cases where the second layer includes a recessed region, the recessed region can include one or more structural support regions. For example, one or more structural support regions can include a metal or material that is the same as a conductor or other material that is more rigid than dielectric such as copper or other metal.

At 1006, a third layer of the circuit board can be formed. The third layer can include a conductor and/or dielectric. In cases where the third layer includes a conductor, the third layer can include a recessed region where the conductor does not overlap with the one or more conductive connectors. In cases where the third layer includes a recessed region, the recessed region can include one or more structural support regions. For example, one or more structural support regions can include a metal or material that is the same as a conductor or other material that is more rigid than dielectric such as copper or other metal.

At 1008, layers can be affixed to one another. A glue, epoxy, or other bonding technique can be used to mount, affix, or connect the first layer to the second layer and mount, affix, or connect the second layer to the third layer. The process of 1002 to 1008 can be repeated for forming and affixing additional layers, including one or more outer layers with gold fingers with a recessed region and potentially structural support.

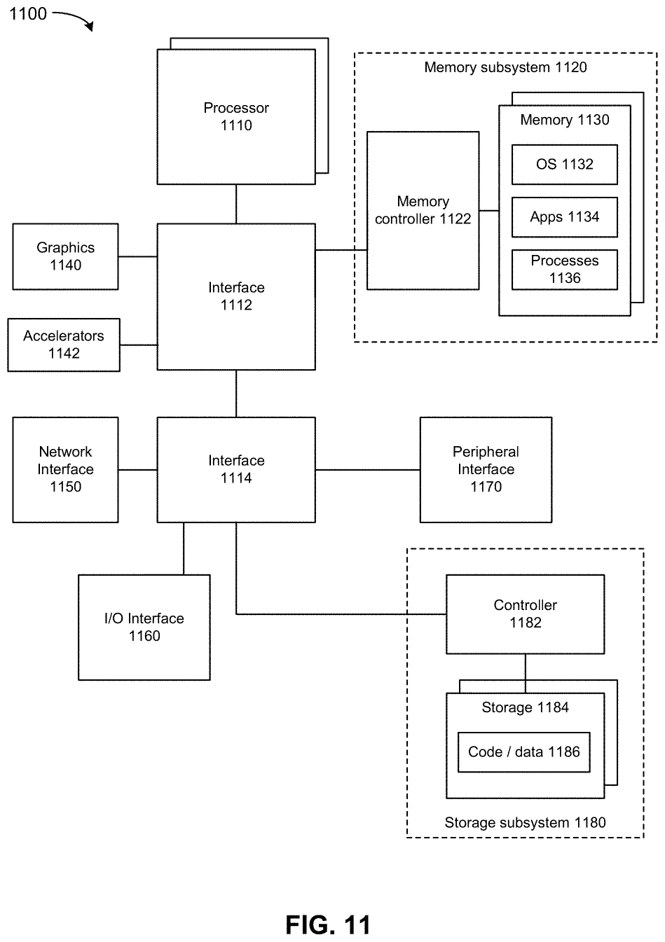

FIG. 11 depicts an example system. The system can use embodiments described herein to form at least one circuit board with recessed conductor regions and potentially structural support. At least one circuit board can couple processor 1110, memory subsystem 1120, or other components described herein. System 1100 includes processor 1110, which provides processing, operation management, and execution of instructions for system 1100. Processor 1110 can include any type of microprocessor, central processing unit (CPU), graphics processing unit (GPU), XPU, processing core, or other processing hardware to provide processing for system 1100, or a combination of processors. An XPU can include one or more of: a CPU, a graphics processing unit (GPU), general purpose GPU (GPGPU), and/or other processing units (e.g., accelerators or programmable or fixed function FPGAs). Processor 1110 controls the overall operation of system 1100, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 1100 includes interface 1112 coupled to processor 1110, which can represent a higher speed interface or a high throughput interface for system components that needs higher bandwidth connections, such as memory subsystem 1120 or graphics interface components 1140, or accelerators 1142. Interface 1112 represents an interface circuit, which can be a standalone component or integrated onto a processor die. Where present, graphics interface 1140 interfaces to graphics components for providing a visual display to a user of system 1100. In one example, graphics interface 1140 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 1140 generates a display based on data stored in memory 1130 or based on operations executed by processor 1110 or both. In one example, graphics interface 1140 generates a display based on data stored in memory 1130 or based on operations executed by processor 1110 or both.

Accelerators 1142 can be a programmable or fixed function offload engine that can be accessed or used by a processor 1110. For example, an accelerator among accelerators 1142 can provide compression (DC) capability, cryptography services such as public key encryption (PKE), cipher, hash/authentication capabilities, decryption, or other capabilities or services. In some embodiments, in addition or alternatively, an accelerator among accelerators 1142 provides field select controller capabilities as described herein. In some cases, accelerators 1142 can be integrated into a CPU socket (e.g., a connector to a motherboard or circuit board that includes a CPU and provides an electrical interface with the CPU). For example, accelerators 1142 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs). Accelerators 1142 can provide multiple neural networks, CPUs, processor cores, general purpose graphics processing units, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 1120 represents the main memory of system 1100 and provides storage for code to be executed by processor 1110, or data values to be used in executing a routine. Memory subsystem 1120 can include one or more memory devices 1130 such as read-only memory (ROM), flash memory, one or more varieties of random access memory (RAM) such as DRAM, or other memory devices, or a combination of such devices. Memory 1130 stores and hosts, among other things, operating system (OS) 1132 to provide a software platform for execution of instructions in system 1100. Additionally, applications 1134 can execute on the software platform of OS 1132 from memory 1130. Applications 1134 represent programs that have their own operational logic to perform execution of one or more functions. Processes 1136 represent agents or routines that provide auxiliary functions to OS 1132 or one or more applications 1134 or a combination. OS 1132, applications 1134, and processes 1136 provide software logic to provide functions for system 1100. In one example, memory subsystem 1120 includes memory controller 1122, which is a memory controller to generate and issue commands to memory 1130. It will be understood that memory controller 1122 could be a physical part of processor 1110 or a physical part of interface 1112. For example, memory controller 1122 can be an integrated memory controller, integrated onto a circuit with processor 1110.

While not specifically illustrated, it will be understood that system 1100 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, system 1100 includes interface 1114, which can be coupled to interface 1112. In one example, interface 1114 represents an interface circuit, which can include standalone components and integrated circuitry. In one example, multiple user interface components or peripheral components, or both, couple to interface 1114. Network interface 1150 provides system 1100 the ability to communicate with remote devices (e.g., servers or other computing devices) over one or more networks. Network interface 1150 can include an Ethernet adapter, wireless interconnection components, cellular network interconnection components, USB (universal serial bus), or other wired or wireless standards-based or proprietary interfaces. Network interface 1150 can transmit data to a device that is in the same data center or rack or a remote device, which can include sending data stored in memory. Network interface 1150 can receive data from a remote device, which can include storing received data into memory. Various embodiments can be used in connection with network interface 1150, processor 1110, and memory subsystem 1120.

In one example, system 1100 includes one or more input/output (I/O) interface(s) 1160. I/O interface 1160 can include one or more interface components through which a user interacts with system 1100 (e.g., audio, alphanumeric, tactile/touch, or other interfacing). Peripheral interface 1170 can include any hardware interface not specifically mentioned above. Peripherals refer generally to devices that connect dependently to system 1100. A dependent connection is one where system 1100 provides the software platform or hardware platform or both on which operation executes, and with which a user interacts.

In one example, system 1100 includes storage subsystem 1180 to store data in a nonvolatile manner. In one example, in certain system implementations, at least certain components of storage 1180 can overlap with components of memory subsystem 1120. Storage subsystem 1180 includes storage device(s) 1184, which can be or include any conventional medium for storing large amounts of data in a nonvolatile manner, such as one or more magnetic, solid state, or optical based disks, or a combination. Storage 1184 holds code or instructions and data 1186 in a persistent state (e.g., the value is retained despite interruption of power to system 1100). Storage 1184 can be generically considered to be a “memory,” although memory 1130 is typically the executing or operating memory to provide instructions to processor 1110. Whereas storage 1184 is nonvolatile, memory 1130 can include volatile memory (e.g., the value or state of the data is indeterminate if power is interrupted to system 1100). In one example, storage subsystem 1180 includes controller 1182 to interface with storage 1184. In one example controller 1182 is a physical part of interface 1114 or processor 1110 or can include circuits or logic in both processor 1110 and interface 1114.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). Another example of volatile memory includes cache or static random access memory (SRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/output version 2, JESD229-2 originally published by JEDEC in August 2014, HBM (High Bandwidth Memory, JESD325, originally published by JEDEC in October 2013, LPDDR5 (currently in discussion by JEDEC), HBM2 (HBM version 2), currently in discussion by JEDEC, or others or combinations of memory technologies, and technologies based on derivatives or extensions of such specifications. The JEDEC standards are available at www.jedec.org.

A non-volatile memory (NVM) device is a memory whose state is determinate even if power is interrupted to the device. In some embodiments, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), Intel® Optane™ memory, NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 1100. More specifically, power source typically interfaces to one or multiple power supplies in system 1100 to provide power to the components of system 1100. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 1100 can be implemented using interconnected compute sleds of processors, memories, storages, network interfaces, and other components. High speed interconnects can be used such as PCIe, Ethernet, or optical interconnects (or a combination thereof).

Embodiments herein may be implemented in various types of computing and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. It is noted that hardware, firmware and/or software elements may be collectively or individually referred to herein as “module,” or “logic.” A processor can be one or more combination of a hardware state machine, digital control logic, central processing unit, or any hardware, firmware and/or software elements.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences of steps may also be performed according to alternative embodiments. Furthermore, additional steps may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”’

Illustrative examples of the devices, systems, and methods disclosed herein are provided below. An embodiment of the devices, systems, and methods may include any one or more, and any combination of, the examples described below.

Flow diagrams as illustrated herein provide examples of sequences of various process actions. The flow diagrams can indicate operations to be executed by a software or firmware routine, as well as physical operations. In some embodiments, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, and so forth.

Example 1 includes one or more examples, and includes an apparatus comprising: a circuit board comprising a plurality of layers and at least one conductive connection, wherein: the at least one conductive connection is connected to a layer of the plurality of layers; at least one layer of the plurality of layers comprises a conductive material, the at least two layers of the plurality of layers comprise conductive material that extend in an axis towards the at least one conductive connection but do not overlap with the at least one layer of the plurality of layers comprising the conductive material.

Example 2 includes one or more examples, wherein the at least one conductive connection comprises at least one gold finger.

Example 3 includes one or more examples, wherein the conductive material comprises a ground plane or signal plane.

Example 4 includes one or more examples, wherein the conductive material comprises one or more of: copper, bronze, or an alloy.

Example 5 includes one or more examples, and includes at least one surface mounted (SMT) connector coupled to the at least one conductive connection.

Example 6 includes one or more examples, wherein the circuit board comprises a dual in-line memory module (DIMM).

Example 7 includes one or more examples, wherein an arrangement of the at least one conductive connection is consistent with Joint Electronic Device Engineering Council Double Data Rate version 5 (DDR5).

Example 8 includes one or more examples, and includes a first device coupled to the circuit board, wherein the first device comprises a surface mounted (SMT) connector of a motherboard, a motherboard, and one or more of: central processing unit (CPU), XPU, accelerator, and/or graphics processing unit (GPU).

Example 9 includes one or more examples, and includes a method comprising: forming a portion of a circuit board by: forming a first layer comprising a conductive layer that extend to a first line; forming a second layer comprising a conductive layer and a dielectric layer; forming a third layer comprising a conductive layer and a dielectric layer; affixing the first layer to the second layer; and affixing the second layer to the third layer, wherein the forming the second layer comprises forming the conductive layer below the first line to form part of a recess region and the forming the third layer comprises forming the conductive layer below the first line to form part of the recess region.

Example 10 includes one or more examples, and includes forming at least one rigid region in the recess region.

Example 11 includes one or more examples, wherein the at least one rigid region comprises at least one metal region.

Example 12 includes one or more examples, wherein the conductive layer that extend to a first line comprises at least one gold finger.

Example 13 includes one or more examples, wherein the conductive layer of the second layer comprises a ground plane or signal plane and the conductive layer of the third layer comprises a ground plane or signal plane.

Example 14 includes one or more examples, wherein the conductive layer of the second layer comprises one or more of: copper, bronze, or an alloy and the conductive layer of the third layer comprises one or more of: copper, bronze, or an alloy.

Example 15 includes one or more examples, wherein the circuit board comprises a dual in-line memory module (DIMM).

Example 16 includes one or more examples, wherein the conductive layer of the first layer comprises at least conductor and an arrangement of the at least conductor is consistent with Joint Electronic Device Engineering Council Double Data Rate version 5 (DDR5).

Example 17 includes one or more examples, and includes a system comprising: a circuit board and a second circuit board, wherein: the circuit board comprises a plurality of layers and at least one conductive connection, the at least one conductive connection is connected to a layer of the plurality of layers, at least one layer of the plurality of layers comprises a conductive material, the at least two layers of the plurality of layers comprise conductive material that extend in an axis towards the at least one conductive connection but do not overlap with the at least one layer of the plurality of layers comprising the conductive material, the conductive material of the at least one layer of the plurality of layers comprises one or more pins, and the second circuit board is conductively coupled to the circuit board by at least the one or more pins.

Example 18 includes one or more examples, wherein the circuit board comprises a dual in-line memory module (DIMM).

Example 19 includes one or more examples, wherein second circuit board comprises a circuit board coupled to one or more of: central processing unit (CPU), XPU, accelerator, graphics processing unit (GPU), and/or network interface device.

Example 20 includes one or more examples, wherein the conductive material comprises a ground plane or signal plane.

What is claimed is:

1. An apparatus comprising:
a circuit board comprising a plurality of layers and at least one conductive connection, wherein:
the at least one conductive connection is connected to a layer of the plurality of layers;
at least one layer of the plurality of layers comprises a conductive material, 178317724the at least two layers of the plurality of layers comprise conductive material that extend in an axis towards the at least one conductive connection but do not overlap with the at least one layer of the plurality of layers comprising the conductive material.

2. The apparatus of claim 1, wherein the at least one conductive connection comprises at least one gold finger.

3. The apparatus of claim 1, wherein the conductive material comprises a ground plane or signal plane.

4. The apparatus of claim 1, wherein the conductive material comprises one or more of: copper, bronze, or an alloy.

5. The apparatus of claim 1, comprising at least one surface mounted (SMT) connector coupled to the at least one conductive connection.

6. The apparatus of claim 1, wherein the circuit board comprises a dual in-line memory module (DIMM).

7. The apparatus of claim 6, wherein an arrangement of the at least one conductive connection is consistent with Joint Electronic Device Engineering Council Double Data Rate version 5 (DDR5).

8. The apparatus of claim 1, further comprising a first device coupled to the circuit board, wherein
the first device comprises a surface mounted (SMT) connector of a motherboard, a motherboard, and one or more of: central processing unit (CPU), XPU, accelerator, and/or graphics processing unit (GPU).

9. A method comprising:
forming a portion of a circuit board by:
forming a first layer comprising a conductive layer that extend to a first line;
forming a second layer comprising a conductive layer and a dielectric layer;
forming a third layer comprising a conductive layer and a dielectric layer;
affixing the first layer to the second layer; and
affixing the second layer to the third layer, wherein
the forming the second layer comprises forming the conductive layer below the first line to form part of a recess region and
the forming the third layer comprises forming the conductive layer below the first line to form part of the recess region.

10. The method of claim 9, comprising:
forming at least one rigid region in the recess region.

11. The method of claim 10, wherein the at least one rigid region comprises at least one metal region.

12. The method of claim 9, wherein the conductive layer that extend to a first line comprises at least one gold finger.

13. The method of claim 9, wherein
the conductive layer of the second layer comprises a ground plane or signal plane and
the conductive layer of the third layer comprises a ground plane or signal plane.

14. The method of claim 9, wherein
the conductive layer of the second layer comprises one or more of: copper, bronze, or an alloy and
the conductive layer of the third layer comprises one or more of: copper, bronze, or an alloy.

15. The method of claim 9, wherein the circuit board comprises a dual in-line memory module (DIMM).

16. The method of claim 9, wherein
the conductive layer of the first layer comprises at least conductor and
an arrangement of the at least conductor is consistent with Joint Electronic Device Engineering Council Double Data Rate version 5 (DDR5).

17. A system comprising:
a circuit board and a second circuit board, wherein:
the circuit board comprises a plurality of layers and at least one conductive connection,
the at least one conductive connection is connected to a layer of the plurality of layers,
at least one layer of the plurality of layers comprises a conductive material,
the at least two layers of the plurality of layers comprise conductive material that extend in an axis towards the at least one conductive connection but do not overlap with the at least one layer of the plurality of layers comprising the conductive material,
the conductive material of the at least one layer of the plurality of layers comprises one or more pins, and
the second circuit board is conductively coupled to the circuit board by at least the one or more pins.

18. The system of claim 17, wherein the circuit board comprises a dual in-line memory module (DIMM).

19. The system of claim 17, wherein second circuit board comprises a circuit board coupled to one or more of: central processing unit (CPU), XPU, accelerator, graphics processing unit (GPU), and/or network interface device.

20. The system of claim 17, wherein the conductive material comprises a ground plane or signal plane.
